(19) United States
(12) Patent Application Publication
(10) Pub. No.: US 2025/0071945 A1
(43) Pub. Date: Feb. 27, 2025

(54) A HEAT SPREADER, AND AN ELECTRONIC MODULE

(71) Applicant: Telefonaktiebolaget LM Ericsson (publ), Stockholm (SE)

(72) Inventors: Per INGELHAG, Alingsås (SE); Peter MELIN, Lindome (SE)

(21) Appl. No.: 18/726,934

(22) PCT Filed: Jan. 20, 2022
(86) PCT No.: PCT/SE2022/050060

§ 371 Date: Jul. 5, 2024

(51) Int. Cl. H05K 7/20; H01L 23/373

(52) U.S. Cl. CPC H05K 7/2039; H01L 23/3731; H01L 23/3736

(57) ABSTRACT

A heat spreader for heat transfer from a heat generating electronic component having a coefficient of thermal expansion, CTE_{X}. The heat spreader includes a plate of a first thermally conductive material with a first side configured to be in thermal contact with the heat generating electronic component, and an opposing second side. The first thermally conductive material has a first CTE, CTE₁; a plurality of holes extending in a direction between the first side and the second side; a second thermally conductive material with a second CTE, CTE₂, disposed in said holes; wherein the heat spreader has a CTE_{C} based on the volume, V₁, of the first thermally conductive material and the CTE₁, and the volume, V₂, of the second thermally conducting material and the CTE₂ such that 0.5<CTE_{X}/CTE_{C}<1.5.

### TECHNICAL FIELD

The present disclosure generally relates to the field of heat spreaders and more specifically to the field of heat spreaders for electronic components, as well as to the field of electronic modules with heat spreaders.

### BACKGROUND

In dense electronic circuits, temperature management is of utmost importance for the safe and reliable operation of the circuits. A circuit on a silicon die often requires efficient cooling in order to keep the circuit within its desired temperature region during operation, and this is especially important for processing circuits and amplifying circuits. In some circuits, it may be easy to integrate a heat sink in contact with the die via a resilient intermediate material such as thermal paste. This intermediate layer is often denoted a thermal interface material, TIM. This type of cooling was used in older circuits with freestanding heat sinks standing from the circuit board. In more recent circuits the enclosure of the electronic device may have an integrated heat sink, for example a lid, that may protect the electronic circuits from environmental dangers such as mechanical interference and harsh environments involving dust and moisture, simultaneously as efficient cooling is provided. The die with the circuit that needs cooling must be thermally connected to the heat sink, and this connection must be thermally efficient as well as allowing thermal stress. In some circuits an intermediate structure is employed to transfer and distribute heat from the die, such an intermediate structure is called a heat spreader. Various designs of heat spreaders exists but the most common passive heat spreader is a plate or block of material having a high thermal conductivity, such as copper, aluminum, diamond, or graphite. A common problem with heat spreaders is that they must be thermally connected to the die that needs heat transfer. This connection is often achieved with the aforementioned thermal interface material, TIM. Thermal paste is an example of a TIM and thermal paste can often comprise metal particles or liquid metal. However, TIM often provides limited heat transfer compared to the heat spreader and this means that the TIM layer should be as thin as possible. If a TIM material with liquid metal is used the thermal conductivity is improved, but a liquid metal TIM material is difficult to handle in production due to reaction with other materials. The TIM material cannot be as thin as possible since the die has a different coefficient of thermal expansion than the heat spreader and the heat sink. This means that the TIM material must be able to withstand mechanical stress due to the different coefficient of thermal expansions of the die and the heat spreader. Recent development in heat spreader technology has shown that graphite has excellent thermal conductivity (4× thermal conductivity of copper) in the basal-plane, whereas the thermal conductivity in a direction perpendicular to the basal-plane is limited.

Thus, it is a need for a heat spreader with excellent thermal conductivity as well as a coefficient of thermal expansion that matches the coefficient of thermal expansion of the die in order to reduce mechanical stress in the TIM layer.

### SUMMARY

An object of the present disclosure is to provide a heat spreader which seeks to mitigate, alleviate, or eliminate one or more of the above-identified deficiencies in the art and disadvantages singly or in any combination and to provide an improved heat spreader.

This object is obtained by a heat spreader for heat transfer from a heat generating electronic component having a coefficient of thermal expansion, CTE_{X} wherein the heat spreader comprises a plate of a first thermally conductive material with a first side configured to be in thermal contact with the heat generating electronic component, and an opposing second side, wherein the first thermally conductive material has a first coefficient of thermal expansion, CTE₁; a plurality of holes extending in a direction between the first side and the second side of the plate, wherein the plurality of holes are disposed in the first region of the plate; a second thermally conductive material with a second coefficient of thermal expansion, CTE₂, disposed in said holes; wherein the heat spreader has a thermal expansion coefficient CTE_{C} in the first region which is based on the volume, V₁, of the first thermally conductive material in the first region and the CTE₁ of the first thermally conductive material, and the volume, V₂, of the second thermally conducting material in the first region and the CTE₂ of the second thermally conductive material such that 0.5<CTE_{X}/CTE_{C}<1.5.

The object is also obtained by an electronic module, comprising: an electronic component with a thermal expansion coefficient, CTE_{X}; a heat spreader in thermal contact with the electronic component wherein the heat spreader comprises a plate of a first thermally conductive material with a first side configured to be in thermal contact with the heat generating component, and an opposing second side, wherein the first thermally conductive material has a first coefficient of thermal expansion, CTE₁; a plurality of holes extending in a direction between the first side and the second side the plate, wherein the plurality of holes are disposed in a first region of the plate; a second thermally conductive material with a second coefficient of thermal expansion, CTE₂, disposed in said holes; wherein the heat spreader has a thermal expansion coefficient CTE_{C} in the first region which is based on the volume, V₁, of the first thermally conducting material in the first region and the CTE₁ of the first thermally conductive material, and the volume, V₂, of the second thermally conducting material in the first region and the CTE₂ of the second thermally conductive material such that 0.5<CTE_{X}/CTE_{C}<1.5.

An advantage of a heat spreader as disclosed above is that the coefficient of thermal expansion of such a heat spreader is possible to adjust to match the coefficient of thermal expansion of the die. Thereby a reduced amount of mechanical stress is induced in the interface between the die and the heat spreader due to thermal expansion. Another advantage is that it also enables the use of mechanical more rigid solutions like sintered TIMs with very high thermal capability.

### BRIEF DESCRIPTION OF THE DRAWINGS

The foregoing will be apparent from the following more particular description of the example embodiments, as illustrated in the accompanying drawings in which like reference characters refer to the same parts throughout the different views. The drawings are not necessarily to scale, emphasis instead being placed upon illustrating the example embodiments.

FIG. 1 is a schematic drawing of a heat spreader according to an embodiment and FIG. 1a is a cross section along line A-A′ of FIG. 1b, which discloses an embodiment of a heat spreader in a top view;

FIG. 2 is a schematic drawing of an electronic module in cross sectional view according to an embodiment; and

FIG. 3 is a schematic cross section through the heat spreader of FIG. 1 along line B-B′ of FIG. 1b;

FIG. 4 is a schematic cross section of an embodiment of a heat spreader along line A-A of FIG. 1b;

FIG. 5 is a schematic cross section of an embodiment of a heat spreader along line A-A′ of FIG. 1b; and

FIG. 6 is schematic drawing of an embodiment of a heat spreader in a top view.

### DETAILED DESCRIPTION

Aspects of the present disclosure will be described more fully hereinafter with reference to the accompanying drawings. The apparatus and method disclosed herein can, however, be realized in many different forms and should not be construed as being limited to the aspects set forth herein. Like numbers in the drawings refer to like elements throughout.

The terminology used herein is for the purpose of describing particular aspects of the disclosure only, and is not intended to limit the invention. As used herein, the singular forms “a”, “an” and “the” are intended to include the plural forms as well, unless the context clearly indicates otherwise.

In this disclosure, the term ‘die’ should be interpreted as a semiconductor substrate with an electronic circuit. The term should also be interpreted to encompass a system on a chip, SoC, which may involve a plurality of different interconnected substrates and circuits.

In this disclosure the term ‘via’ should be interpreted as a structure that provides conductivity, either thermal or electric or both, between different layers of a multilayer structure.

In this disclosure, the acronym ‘CTE’ is used for coefficient of thermal expansion, which is a material property that is indicative of the extent to which a material expands upon temperature change.

Some of the example embodiments presented herein are directed towards a heat spreader. As part of the development of the example embodiments presented herein, a problem will first be identified and discussed. A heat spreader made of graphite has excellent thermal conductivity in the basal plane, whereas the thermal conductivity perpendicular to the basal plane is approximately twenty times lower. However, the heat spreader of graphite has a CTE of about 0.5 ppm/° C. in the basal plane, and a silicon die may have a CTE of 3 ppm/° C., which is about six times higher. This causes large differences in thermal expansion and the TIM layer absorbs these differences. Otherwise, there is an increased risk for cracks in the die and/or in the heat spreader. In some cases, this means that a thick and resilient TIM layer may be used and this has a negative impact on the heat transfer from the die to the heat spreader, since a thicker resilient TIM layer results in an increased thermal resistance compared to the heat spreader and the die that emits heat.

The present inventors realized that these problems may be minimized or even eliminated by forming a heat spreader from a plate of graphite and providing the plate with a plurality of holes filled with a material with a CTE different from the CTE of graphite. By tailoring the density, fill material and dimensions of these holes, it is possible to adjust the CTE of the heat spreader for matching the CTE of the die. The present inventors have demonstrated that it is possible to match the CTE of the die with the CTE of the heat spreader.

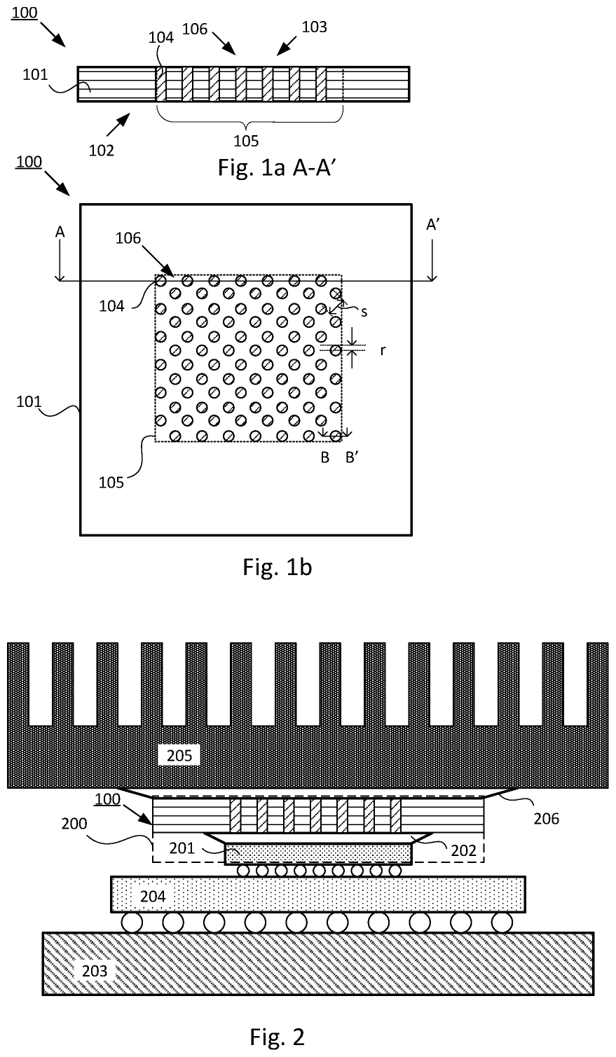

Now with reference made to FIGS. 1a, 1b and 2 a first example of a heat spreader will be described. The heat spreader, generally denoted 100, for heat transfer from a heat generating electronic component 201 having a coefficient of thermal expansion, CTE_{X}. The heat spreader 100 comprises a plate 101 of a first thermally conductive material with a first side 102 configured to be in thermal contact with the heat generating electronic component 201, and an opposing second side 103.

The first thermally conductive material has a first coefficient of thermal expansion, CTE₁. The heat spreader further comprises a plurality of holes 106 extending in a direction between the first side 102 and the second side 103 of the plate 101. The plurality of holes are disposed in the first region 105 of the plate 101. A second thermally conductive material 104 with a second coefficient of thermal expansion, CTE₂, is disposed in said holes 106.

The heat spreader 100 has a thermal expansion coefficient CTE_{C} in the first region 105 which is based on the volume, V₁, of the first thermally conductive material in a first region 105 and the CTE₁ of the first thermally conductive material, and the volume, V₂, of the second thermally conducting material in the first region 105 and the CTE₂ of the second thermally conductive material such that 0.5<CTE_{X}/CTE_{C}<1.5.

This way thermal expansion coefficient matching between the first region 105 and the heat-generating component is possible and may thus reduce the need for a thick TIM layer.

The thermal expansion coefficient CTE_{C} n the first region 105 is expressed with the following equation:

$${CTE}_{C} = ( {V}_{1} \cdot {CTE}_{1} + {V}_{2} \cdot {CTE}_{2} ) / ( {V}_{1} + {V}_{2} )$$

where V₁ is the volume of the first thermally conductive material in the first region of the plate, and V₂ is the volume of the second thermally conductive material disposed in said holes 106;404,405;504 of the first region 105.

This suggests that the CTE_{C} in the first region may be adjusted by means of varying the volumes and the material of the second thermally conducting material

The first example disclosed in FIG. 1 has filled through holes. The heat spreader 100 has a coefficient of thermal expansion CTE_{C} in the first region 105 expressed with the following equation:

$${CTE}_{C} = ( {CTE}_{2} \cdot π \cdot {r}^{2} + {CTE}_{1} \cdot ( {s}^{2} \cdot √ 3 / 2 - π \cdot {r}^{2} ) ) / ( {s}^{2} \cdot √ 3 / 2 )$$

where s is a centre distance between adjacent holes 106, wherein the holes have parallel centre axes, r is the radius of a hole of the plurality of holes. The plate 101 has a uniform thickness in the first region 105, and r and s are chosen such that 0.5<CTE_{X}/CTE_{C}<1.5.

By choosing r and s such that the CTE_{X}/CTE_{C} is within the above interval a very good CTE match between the heat spreader and the electronic component 201 may be achieved.

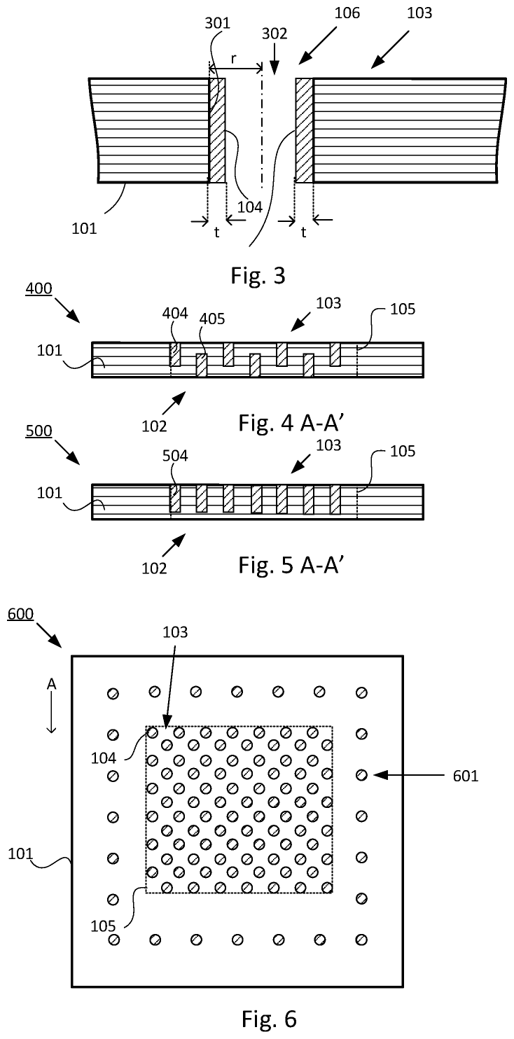

Optionally, the second thermally conductive material 104 disposed in the plurality of holes is disposed on the walls 301 of the plurality of holes with a thickness t as shown in FIG. 3, such that an opening 302 extends in the hole. The coefficient of thermal expansion CTE_{C} in the first region 105 of the heat spreader 100 is expressed with the following equation:

$${CTE}_{C} = ( {CTE}_{2} \cdot π \cdot ( {r}^{2} - {( r - t )}^{2} ) + {CTE}_{1} \cdot ( {s}^{2} \cdot √ 3 / 2 - π \cdot {r}^{2} ) ) / ( {s}^{2} \cdot √ 3 / 2 )$$

where s is a centre distance between adjacent holes 106 and r is the radius of a hole of the plurality of holes, and t is the thickness of the second thermally conductive material disposed on the walls of the plurality of holes. The r, t and s are chosen such that 0.5<CTE_{X}/CTE_{C}<1.5.

The first thermally conductive material is graphite in FIGS. 1 and 2.

The second thermally conductive material 104 is copper in FIGS. 1 and 2. This second thermally conductive material may be deposited on the plate 101 by means of plating and may cover the first side and/or the second side of the plate 101. This means that the first side and/or the second side may be provided with the second thermally conductive material and if this is unwanted, a simple grinding step will remove it for example.

Advantageously, the thermal conductivity of the first thermally conductive material in the longitudinal direction of the holes is smaller than the thermal conductivity of the second thermally conductive material disposed in the holes.

Now with reference made to FIG. 6 an example of a heat spreader, generally designated 600, is disclosed in this example the plate 101 outside the first region 105 comprises further holes 601, wherein the further holes have the second thermally conducting material disposed on the walls thereof.

This way the CTE_{C} may gradually be changed to match the CTE₁ of the first thermally conductive material. This may decrease the risk of crack formation due to different CTE in the first region and the surrounding material of the plate.

Optionally, the heat spreader has a thermal expansion coefficient in the first region 105 in the interval: 1.5 ppm/° C.<CTE_{C}<4.5 ppm/° C. for matching a coefficient of thermal expansion of a heat generating electronic component with a coefficient of thermal expansion of 3.0 ppm/° C.

FIG. 2 discloses an electronic module, generally designated 200, comprising an electronic component 201 with a thermal expansion coefficient, CTE_{X}, a heat spreader 100 in thermal contact with the electronic component 201. The heat spreader 100 comprises a plate 101 of a first thermally conductive material with a first side 102 configured to be in thermal contact with the heat generating component 201, and an opposing second side 103. The first thermally conductive material has a first coefficient of thermal expansion, CTE₁. The heat spreader 100 further comprises a plurality of holes 106 extending in a direction between the first side 102 and the second side 103 the plate 101. The plurality of holes are disposed in a first region 105 of the plate. A second thermally conductive material 104 with a second coefficient of thermal expansion, CTE₂, is disposed in said holes 106. The heat spreader 100 has a thermal expansion coefficient CTE_{C} in the first region 105 which is based on the volume, V₁, of the first thermally conducting material in the first region 105 and the CTE₁ of the first thermally conductive material, and the volume, V₂, of the second thermally conducting material in the first region 105 and the CTE₂ of the second thermally conductive material such that 0.5<CTE_{X}/CTE_{C}<1.5.

Optionally, the electronic module 200 has a coefficient of thermal expansion CTE_{C} in the first region 105 of the heat spreader 100 that is expressed with the following equation:

$${CTE}_{C} = ( {V}_{1} \cdot {CTE}_{1} + {V}_{2} \cdot {CTE}_{2} ) / ( {V}_{1} + {V}_{2} )$$

where V₁ is the volume of the first thermally conducting material in the first region 105 of the plate, and V₂ is the volume of the second thermally conductive material disposed in said holes 106 of the first region 105.

Optionally, the electronic module 200 has a heat spreader 100 that has a thermal expansion coefficient CTE_{C} in the first region 105 expressed with the following equation:

$${CTE}_{C} = ( {CTE}_{2} \cdot π \cdot {r}^{2} + {CTE}_{1} \cdot ( {s}^{2} \cdot √ 3 / 2 - π \cdot {r}^{2} ) ) / ( {s}^{2} \cdot √ 3 / 2 )$$

where s is a centre distance between adjacent holes, wherein the holes have parallel centre axes; r is the radius of a hole of the plurality of holes; the plate 101 has a uniform thickness in the first region 105; and wherein r and s are chosen such that 0.5<CTE_{X}/CTE_{C}<1.5.

Optionally, the electronic module 200 has a heat spreader 100 that has a second thermally conductive material 104 disposed in the plurality of holes on the walls 301 of the plurality of holes with a thickness t, such that an opening 302 extends in the hole. The coefficient of thermal expansion CTE_{C} in the first region 105 of the heat spreader 100 is expressed with the following equation:

$${CTE}_{C} = ( {CTE}_{2} \cdot π \cdot ( {r}^{2} - {( r - t )}^{2} ) + {CTE}_{1} \cdot ( {s}^{2} \cdot √ 3 / 2 - π \cdot {r}^{2} ) ) / ( {s}^{2} \cdot √ 3 / 2 )$$

where s is a centre distance between adjacent holes 106; r is the radius of a hole of the plurality of holes 106; t is the thickness of the second thermally conductive material disposed on the walls of the plurality of holes, and wherein r, t and s are chosen such that 0.5<CTE_{X}/CTE_{C}<1.5.

Optionally, the first thermally conductive material of the heat spreader 100 of the electronic module 200 is graphite.

Optionally, the second thermally conductive material 104 of the heat spreader 100 of the electronic module 200 is copper.

Advantageously, the thermal conductivity of the first thermally conductive material in the longitudinal direction of the holes is smaller than the thermal conductivity of the second thermally conductive material disposed in the holes of the heat spreader of the electronic module.

Optionally, the plate 101 of the heat spreader of the electronic module outside the first region comprises further holes 601, wherein the further holes have the second thermally conducting material disposed on the walls thereof.

Optionally, the heat spreader of the electronic module has a coefficient of thermal expansion in the first region 105 in the interval: 1.5 ppm/° C.<CTE_{C}<4.5 ppm/° C. for matching a coefficient of thermal expansion of the electronic component CTE_{X} of 3.0 ppm/° C.

As shown in FIG. 2, the electronic component 201 is in thermal contact with at least a part of the first region 105 of the plate 101. In some embodiments the first region may be larger than the electronic component, and in some embodiments, the first region may be smaller than the electronic component. For example, some heat generating parts of the electronic component is in thermal contact with the first region of the heat spreader, such as power transistors.

The electronic component 201 is thermally connected to the first region 105 of the plate 101 by means of a thermal interface material 202.

The electronic module 200 is in thermal contact with a heat sink 205 by means of a further TIM layer 206. The electronic module 200 being soldered or bonded to a circuit board 204. The circuit board 204 is connected to a printed circuit board 203. The CTE of the heat spreader may be tailored to both the CTE of the heat sink 205 and to the CTE of the electronic component 201.

In FIG. 4 an embodiment of a cross section along A-A′ of a heat spreader 400 is disclosed. This embodiment has a plurality of holes 405 that extends from the first side 102 into the plate 101, further holes 404 extends from the second side 103 into the plate 101. In this embodiment the holes extend into the plate but not through the plate. By arranging the holes in different patterns, it is possible to minimize bending due to thermal expansion in the first region.

In FIG. 5 an embodiment of a cross section along A-A′ of a heat spreader 500 is disclosed. This embodiment has a plurality of holes 504 that extends from the second side 103 into the plate 101, but not through the plate.

The disclosure relates to a heat spreader for heat transfer from a heat generating electronic component having a coefficient of thermal expansion, CTE_{X} wherein the heat spreader comprises a plate of a first thermally conductive material with a first side configured to be in thermal contact with the heat generating electronic component, and an opposing second side, wherein the first thermally conductive material has a first coefficient of thermal expansion, CTE₁; a plurality of holes extending in a direction between the first side and the second side of the plate, wherein the plurality of holes are disposed in the first region of the plate; a second thermally conductive material with a second coefficient of thermal expansion, CTE₂, disposed in said holes; wherein the heat spreader has a thermal expansion coefficient CTE_{C} in the first region which is based on the volume, V₁, of the first thermally conductive material in the first region and the CTE₁ of the first thermally conductive material, and the volume, V₂, of the second thermally conducting material in the first region and the CTE₂ of the second thermally conductive material such that 0.5<CTE_{X}/CTE_{C}<1.5.

According to some embodiments, the thermal expansion coefficient CTE_{C} in the first region is expressed with the following equation:

$${CTE}_{C} = ( {V}_{1} \cdot {CTE}_{1} + {V}_{2} \cdot {CTE}_{2} ) / ( {V}_{1} + {V}_{2} )$$

where V₁ is the volume of the first thermally conductive material in the first region of the plate, and V₂ is the volume of the second thermally conductive material disposed in said holes of the first region.

According to some embodiments, the heat spreader has a coefficient of thermal expansion CTEc in the first region is expressed with the following equation:

$${CTE}_{C} = ( {CTE}_{2} \cdot π \cdot {r}^{2} + {CTE}_{1} \cdot ( {s}^{2} \cdot √ 3 / 2 - π \cdot {r}^{2} ) ) / ( {s}^{2} \cdot √ 3 / 2 )$$

where s is a centre distance between adjacent holes, wherein the holes have parallel centre axes; r is the radius of a hole of the plurality of holes; the plate has a uniform thickness in the first region; and wherein r and s are chosen such that 0.5<CTE_{X}/CTE_{C}<1.5.

According to some embodiments, the second thermally conductive material disposed in the plurality of holes is disposed on the walls of the plurality of holes with a thickness t, such that an opening extends in the hole, wherein the coefficient of thermal expansion CTE_{C} in the first region of the heat spreader is expressed with the following equation:

$${CTE}_{C} = ( {CTE}_{2} \cdot π \cdot ( {r}^{2} {-}^{2} ) + {CTE}_{1} \cdot ( {s}^{2} \cdot √ 3 / 2 - π \cdot {r}^{2} ) ) / ( {s}^{2} \cdot √ 3 / 2 )$$

where s is a centre distance between adjacent holes; r is the radius of a hole of the plurality of holes; t is the thickness of the second thermally conductive material disposed on the walls of the plurality of holes, and wherein r, t and s are chosen such that 0.5<CTE_{X}/CTE_{C}<1.5.

According to some embodiments, the first thermally conductive material is graphite.

According to some embodiments, the second thermally conductive material is copper.

According to some embodiments, the thermal conductivity of the first thermally conductive material in the longitudinal direction of the holes is smaller than the thermal conductivity of the second thermally conductive material disposed in the holes.

According to some embodiments, wherein the plate outside the first region comprises further holes, wherein the further holes have the second thermally conducting material disposed on the walls thereof.

According to some embodiments, wherein the heat spreader has a thermal expansion coefficient in the first region in the interval: 1.5 ppm/° C.<CTE_{C}<4.5 ppm/° C. for matching a coefficient of thermal expansion of a heat generating electronic component with a coefficient of thermal expansion of 3.0 ppm/° C.

The disclosure also relates to an electronic module, comprising: an electronic component with a thermal expansion coefficient, CTE_{X}; a heat spreader in thermal contact with the electronic component wherein the heat spreader comprises a plate of a first thermally conductive material with a first side configured to be in thermal contact with the heat generating component, and an opposing second side, wherein the first thermally conductive material has a first coefficient of thermal expansion, CTE₁; a plurality of holes extending in a direction between the first side and the second side the plate, wherein the plurality of holes are disposed in a first region of the plate; a second thermally conductive material with a second coefficient of thermal expansion, CTE₂, disposed in said holes; wherein the heat spreader has a thermal expansion coefficient CTE_{C} in the first region which is based on the volume, V₁, of the first thermally conducting material in the first region and the CTE₁ of the first thermally conductive material, and the volume, V₂, of the second thermally conducting material in the first region and the CTE₂ of the second thermally conductive material such that 0.5<CTE_{X}/CTE_{C}<1.5.

According to some embodiments, the coefficient of thermal expansion CTE_{C} in the first region of the heat spreader is expressed with the following equation:

$${CTE}_{C} = ( {V}_{1} \cdot {CTE}_{1} + {V}_{2} \cdot {CTE}_{2} ) / ( {V}_{1} + {V}_{2} )$$

where V₁ is the volume of the first thermally conducting material in the first region of the plate, and V₂ is the volume of the second thermally conductive material disposed in said holes of the first region.

According to some embodiments, the heat spreader has a thermal expansion coefficient CTE_{C} in the first region expressed with the following equation:

$${CTE}_{C} = ( {CTE}_{2} \cdot π \cdot {r}^{2} + {CTE}_{1} \cdot ( {s}^{2} \cdot √ 3 / 2 - π \cdot {r}^{2} ) ) / ( {s}^{2} \cdot √ 3 / 2 )$$

where s is a centre distance between adjacent holes, wherein the holes have parallel centre axes; r is the radius of a hole of the plurality of holes; the plate has a uniform thickness in the first region; and wherein r and s are chosen such that 0.5<CTE_{X}/CTE_{C}<1.5.

According to some embodiments, the second thermally conductive material disposed in the plurality of holes is disposed on the walls of the plurality of holes with a thickness t, such that an opening extends in the hole, wherein the coefficient of thermal expansion CTE_{C} in the first region of the heat spreader is expressed with the following equation:

$${CTE}_{C} = ( {CTE}_{2} \cdot π \cdot ( {r}^{2} {-}^{2} ) + {CTE}_{1} \cdot ( {s}^{2} \cdot √ 3 / 2 - π \cdot {r}^{2} ) ) / ( {s}^{2} \cdot √ 3 / 2 )$$

where s is a centre distance between adjacent holes; r is the radius of a hole of the plurality of holes; t is the thickness of the second thermally conductive material disposed on the walls of the plurality of holes, and wherein r, t and s are chosen such that 0.5<CTE_{X}/CTE_{C}<1.5.

According to some embodiments, the first thermally conductive material is graphite.

According to some embodiments, the second thermally conductive material is copper.

According to some embodiments, the thermal conductivity of the first thermally conductive material in the longitudinal direction of the holes is smaller than the thermal conductivity of the second thermally conductive material disposed in the holes.

According to some embodiments, the plate outside the first region comprises further holes, wherein the further holes have the second thermally conducting material disposed on the walls thereof.

According to some embodiments, the heat spreader has a coefficient of thermal expansion in the first region in the interval: 1.5 ppm/° C.<CTE_{C}<4.5 ppm/° C. for matching a coefficient of thermal expansion of the electronic component CTE_{X} of 3.0 ppm/° C.

According to some embodiments, the electronic component is in thermal contact with at least a part of the first region of the plate.

According to some embodiments, the electronic component is thermally connected to the first region of the plate by means of a thermal interface material.

In the drawings and specification, there have been disclosed exemplary embodiments. However, many variations and modifications can be made to these embodiments. Accordingly, although specific terms are employed, they are used in a generic and descriptive sense only and not for purposes of limitation, the scope of the embodiments being defined by the following claims.

The description of the example embodiments provided herein have been presented for purposes of illustration. The description is not intended to be exhaustive or to limit example embodiments to the precise form disclosed, and modifications and variations are possible in light of the above teachings or may be acquired from practice of various alternatives to the provided embodiments. The examples discussed herein were chosen and described in order to explain the principles and the nature of various example embodiments and its practical application to enable one skilled in the art to utilize the example embodiments in various manners and with various modifications as are suited to the particular use contemplated. The features of the embodiments described herein may be combined in all possible combinations of methods, apparatus, modules, systems, and computer program products.

It should be appreciated that the example embodiments presented herein may be practiced in any combination with each other. It should be noted that the word “comprising” does not necessarily exclude the presence of other elements or steps than those listed and the words “a” or “an” preceding an element do not exclude the presence of a plurality of such elements. It should further be noted that any reference signs do not limit the scope of the claims, that the example embodiments may be implemented at least in part by means of both hardware and software, and that several “means”, “units” or “devices” may be represented by the same item of hardware.

1. A heat spreader for heat transfer from a heat generating electronic component having a coefficient of thermal expansion, CTE_{X}, the heat spreader comprising:
a plate of a first thermally conductive material with a first side configured to be in thermal contact with the heat generating electronic component, and an opposing second side, wherein the first thermally conductive material has a first coefficient of thermal expansion, CTE₁;
a plurality of holes extending in a direction between the first side and the second side of the plate, wherein the plurality of holes are disposed in a first region of the plate;
a second thermally conductive material with a second coefficient of thermal expansion, CTE₂, disposed in said holes;
wherein the heat spreader has a thermal expansion coefficient CTE_{C} in the first region which is based on the volume, V₁, of the first thermally conductive material in the first region and the CTE₁ of the first thermally conductive material, and the volume, V₂, of the second thermally conducting material in the first region and the CTE₂ of the second thermally conductive material such that 0.5<CTE_{X}/CTE_{C}<1.5.

2. The heat spreader according to claim 1, wherein the thermal expansion coefficient CTE_{C} in the first region is expressed with the following equation:
$${CTE}_{C} = ( {V}_{1} \cdot {CTE}_{1} + {V}_{2} \cdot {CTE}_{2} ) / ( {V}_{1} + {V}_{2} )$$
where V₁ is the volume of the first thermally conductive material in the first region of the plate, and V₂ is the volume of the second thermally conductive material disposed in said holes of the first region.

3. The heat spreader according to claim 1, wherein:
the heat spreader has a coefficient of thermal expansion CTE_{C} in the first region is expressed with the following equation:
$${CTE}_{C} = ( {CTE}_{2} \cdot π \cdot {r}^{2} + {CTE}_{1} \cdot ( {s}^{2} \cdot √ 3 / 2 - π \cdot {r}^{2} ) ) / ( {s}^{2} \cdot √ 3 / 2 )$$
where s is a centre distance between adjacent holes, wherein the holes have parallel centre axes;
r is the radius of a hole of the plurality of holes;
the plate has a uniform thickness in the first region; and
wherein r and s are chosen such that 0.5<CTE_{X}/CTE_{C}<1.5.

4. The heat spreader according to claim 1, wherein the second thermally conductive material disposed in the plurality of holes is disposed on the walls of the plurality of holes with a thickness t, such that an opening extends in the hole, wherein the coefficient of thermal expansion CTE_{C} in the first region of the heat spreader is expressed with the following equation:
$${CTE}_{C} = ( {CTE}_{2} \cdot π \cdot ( {r}^{2} - {( r - t )}^{2} ) + {CTE}_{1} \cdot ( {s}^{2} \cdot √ 3 / 2 - π \cdot {r}^{2} ) ) / ( {s}^{2} \cdot √ 3 / 2 )$$
where s is a centre distance between adjacent holes;
r is the radius of a hole of the plurality of holes;
t is the thickness of the second thermally conductive material disposed on the walls of the plurality of holes, and
wherein r, t and s are chosen such that 0.5<CTE_{X}/CTE_{C}<1.5.

5. The heat spreader according to claim 1, wherein the first thermally conductive material is graphite.

6. The heat spreader according to claim 1, wherein the second thermally conductive material is copper.

7. The heat spreader according to claim 1, wherein the thermal conductivity of the first thermally conductive material in the longitudinal direction of the holes is smaller than the thermal conductivity of the second thermally conductive material disposed in the holes.

8. The heat spreader according to claim 1, wherein the plate outside the first region comprises further holes, wherein the further holes have the second thermally conducting material disposed on the walls thereof.

9. The heat spreader according to claim 1, wherein the heat spreader has a thermal expansion coefficient in the first region (105) in the interval: 1.5 ppm/° C.<CTE_{C}<4.5 ppm/°° C. for matching a coefficient of thermal expansion of a heat generating electronic component with a coefficient of thermal expansion of 3.0 ppm/°° C.

10. An electronic module, comprising:
an electronic component with a thermal expansion coefficient, CTE_{X}; and
a heat spreader in thermal contact with the electronic component, wherein the heat spreader comprises:
a plate of a first thermally conductive material with a first side configured to be in thermal contact with the heat generating component, and an opposing second side, wherein the first thermally conductive material has a first coefficient of thermal expansion, CTE₁;
a plurality of holes extending in a direction between the first side and the second side the plate, wherein the plurality of holes are disposed in a first region of the plate;
a second thermally conductive material with a second coefficient of thermal expansion, CTE₂, disposed in said holes;
wherein the heat spreader has a thermal expansion coefficient CTE_{C} in the first region which is based on the volume, V₁, of the first thermally conducting material in the first region and the CTE₁ of the first thermally conductive material, and the volume, V₂, of the second thermally conducting material in the first region and the CTE₂ of the second thermally conductive material such that 0.5<CTE_{X}/CTE_{C}<1.5.

11. The electronic module according to claim 10, wherein the coefficient of thermal expansion CTE_{C} in the first region of the heat spreader is expressed with the following equation:
$${CTE}_{C} = ( {V}_{1} \cdot {CTE}_{1} + {V}_{2} \cdot {CTE}_{2} ) / ( {V}_{1} + {V}_{2} )$$
where V₁ is the volume of the first thermally conducting material in the first region of the plate, and V₂ is the volume of the second thermally conductive material disposed in said holes of the first region.

12. The electronic module according to claim 10, wherein the heat spreader has a thermal expansion coefficient CTE_{C} in the first region expressed with the following equation:
$${CTE}_{C} = ( {CTE}_{2} \cdot π \cdot {r}^{2} + {CTE}_{1} \cdot ( {s}^{2} \cdot √ 3 / 2 - π \cdot {r}^{2} ) ) / ( {s}^{2} \cdot √ 3 / 2 )$$
where s is a centre distance between adjacent holes, wherein the holes have parallel centre axes;
r is the radius of a hole of the plurality of holes;
the plate has a uniform thickness in the first region; and
wherein r and s are chosen such that 0.5<CTE_{X}/CTE_{C}<1.5.

13. The electronic module according to claim 10, wherein the second thermally conductive material disposed in the plurality of holes is disposed on the walls of the plurality of holes with a thickness t, such that an opening extends in the hole, wherein the coefficient of thermal expansion CTE_{C} in the first region of the heat spreader is expressed with the following equation:
$${CTE}_{C} = ( {CTE}_{2} \cdot π \cdot ( {r}^{2} - {( r - t )}^{2} ) + {CTE}_{1} \cdot ( {s}^{2} \cdot √ 3 / 2 - π \cdot {r}^{2} ) ) / ( {s}^{2} \cdot √ 3 / 2 )$$
where s is a centre distance between adjacent holes;
r is the radius of a hole of the plurality of holes;
t is the thickness of the second thermally conductive material disposed on the walls of the plurality of holes, and
wherein r, t and s are chosen such that 0.5<CTE_{X}/CTE_{C}<1.5.

14. The electronic module according to claim 10, wherein the first thermally conductive material is graphite.

15. The electronic module according to claim 10, wherein the second thermally conductive material is copper.

16. The electronic module according to claim 10, wherein the thermal conductivity of the first thermally conductive material in the longitudinal direction of the holes is smaller than the thermal conductivity of the second thermally conductive material disposed in the holes.

17. The electronic module according to claim 10, wherein the plate outside the first region comprises further holes, wherein the further holes have the second thermally conducting material disposed on the walls thereof.

18. The electronic module according to claim 10, wherein the heat spreader has a coefficient of thermal expansion in the first region in the interval: 1.5 ppm/° C.<CTE_{C}<4.5 ppm/° C. for matching a coefficient of thermal expansion of the electronic component CTE_{X} of 3.0 ppm/° C.

19. The electronic module according to claim 10, wherein the electronic component is in thermal contact with at least a part of the first region of the plate.

20. The electronic module according to claim 10, wherein the electronic component is thermally connected to the first region of the plate by means of a thermal interface material.
